(19) United States
(12) Patent Application Publication
(10) Pub. No.: US 2018/0233336 A1
(43) Pub. Date: Aug. 16, 2018

(54) PROCESSING APPARATUS AND COLLIMATOR

(71) Applicant: Kabushiki Kaisha Toshiba, Minato-ku (JP)

(72) Inventors: Yoshinori TOKUDA, Yokohama (JP); Yasuhiro NOJIRI, Yokohama (JP); Shiguma KATO, Yokohama (JP); Takahiro TERADA, Yokohama (JP); Masakatsu TAKEUCHI, Obu (JP); Yasuhiro AOYAMA, Yokkaichi (JP)

(73) Assignee: Kabushiki Kaisha Toshiba, Minato-ku (JP)

(21) Appl. No.: 15/750,922

(22) PCT Filed: Dec. 19, 2016
(86) PCT No.: PCT/JP2016/087823

§ 371 Date: Feb. 7, 2018

(30) Foreign Application Priority Data
Mar. 15, 2016 (JP) 2016-051283

(51) Int. Cl. H01J 37/34; C23C 14/35

(52) U.S. Cl. CPC H01J 37/3447; C23C 14/35; H01J 2237/3323; H01J 37/347; H01J 37/3405

(57) ABSTRACT

A processing apparatus according to an embodiment includes a container, a workpiece placement unit, a collimator, and a magnetic field generation unit. The workpiece placement unit on which a workpiece is to be placed so that particles are stacked on the workpiece is provided inside the container. The collimator is provided inside the container, and includes a first surface, a second surface opposite to the first surface, and a through hole penetrating the first surface and the second surface. The magnetic field generation unit is provided inside the container and generates a magnetic field between the first surface and the second surface inside the through hole.

### FIELD

Embodiments relate to a processing apparatus and a collimator.

### BACKGROUND

In related art, there is a known processing apparatus such as a sputtering system provided with a collimator.

### CITATION LIST

### Patent Literature

Patent Literature 1: Japanese Laid-open Patent Publication No. 2005-72028

### SUMMARY OF THE INVENTION

### Problem to be Solved by the Invention

For example, if possible to achieve a processing apparatus and a collimator which are provided with a novel structure having less inconvenience, for example, unevenness of a film thickness of a workpiece depending on a location is reduced, such processing apparatus and collimator would be advantageous.

### Means for Solving Problem

A processing apparatus according to an embodiment includes a container, a workpiece placement unit, a collimator, and a magnetic field generation unit. The workpiece placement unit on which a workpiece is to be placed so that particles are stacked on the workpiece is provided inside the container. The collimator is provided inside the container, and includes a first surface, a second surface opposite to the first surface, and a through hole penetrating the first surface and the second surface. The magnetic field generation unit is provided inside the container and generates a magnetic field between the first surface and the second surface inside the through hole.

### BRIEF DESCRIPTION OF DRAWINGS

FIG. 1 is a schematic and exemplary cross-sectional view of a processing apparatus according to an embodiment.

FIG. 2 is a schematic and exemplary cross-sectional view of a portion including a through hole of a collimator according to a first embodiment.

FIG. 3 is a schematic and exemplary explanatory view including a plan view of the collimator according to the first embodiment and an enlarged view of a part thereof.

FIG. 4 is a schematic and exemplary cross-sectional view of a collimator according to a second embodiment.

FIG. 5 is a schematic and exemplary exploded cross-sectional view of the collimator according to second embodiment.

FIG. 6 is a schematic and exemplary cross-sectional view of a collimator of a modification.

### DETAILED DESCRIPTION

In the following, exemplary embodiments of a processing apparatus and a collimator will be disclosed. Note that structures and control (technical features) of the embodiments described below and functions and results (effects) brought by the structures and control are examples. In the drawings, a V direction (first direction) and an H direction (second direction) are defined for convenience of description. The V direction is a vertical direction, and the H direction is a horizontal direction. The V direction and the H direction are orthogonal to each other.

Additionally, a plurality of embodiments in the following includes similar constituent elements. In the following, note that each of such similar constituent elements will be denoted by a common reference sign and repetition of the same description therefor may be omitted.

### First Embodiment

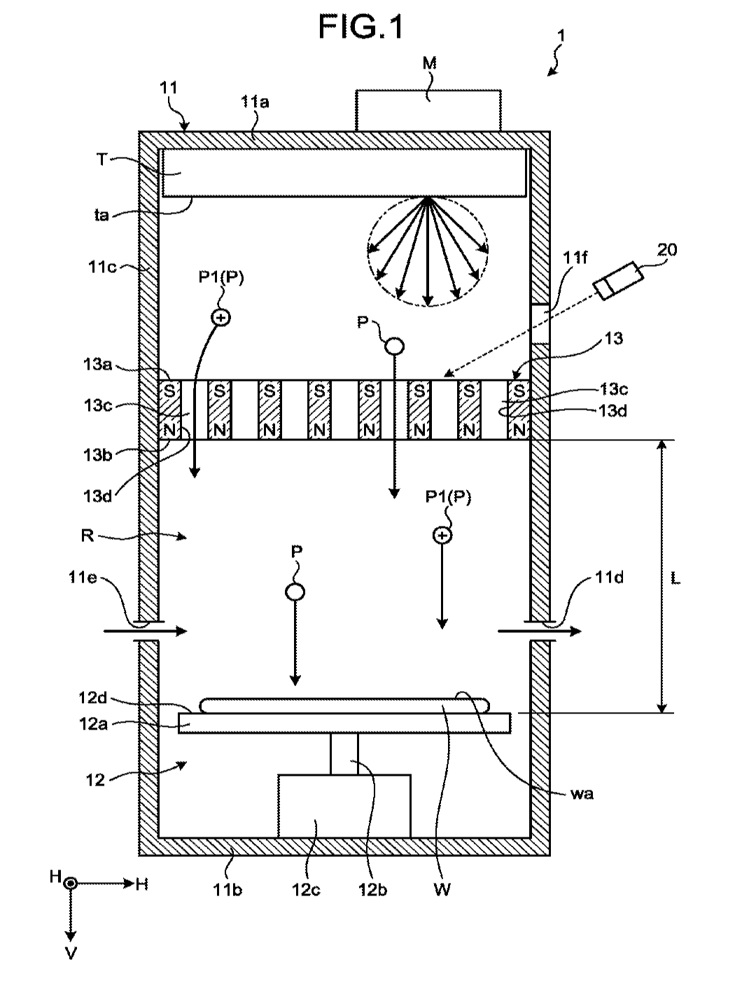

FIG. 1 is a cross-sectional view of a sputtering system 1. In the sputtering system 1, for example, a film made of metal particles P is formed (stacked) on a surface of a wafer W. The spluttering system 1 is an example of a processing apparatus and can be referred to as a film forming device or a stacking device. The wafer W is an example of a workpiece and can be referred to as an object.

The sputtering system 1 has a chamber 11. The chamber 11 is formed in a substantially cylindrical shape centering a central axis along a V direction, and has a top wall 11a, a bottom wall 11b, and a peripheral wall 11c (side wall). The top wall 11a and the bottom wall 11b are orthogonal to the V direction and extend along the H direction. A bus line of the peripheral wall 11c extends along the V direction. A processing chamber R is formed of this chamber 11 as a substantially cylindrical space. The sputtering system 1 is installed in a manner such that the central axis (V direction) of the chamber 11 conforms to the vertical direction, for example. The chamber 11 is an example of a container.

Inside the processing chamber R of the sputtering system 1, a target T can be placed along the top wall 11a. The target T is supported by the top wall 11a via a backing plate, for example. The target T generates metal particles P. The target T can be referred to as a particle emitting source or particle generating source. The top wall 11a or the backing plate can be referred to as a source placement member.

A magnet M can be arranged along the top wall 11a outside the processing chamber R of the sputtering system 1. The target T generates the metal particles P from a region close to the magnet M.

Inside the processing chamber R of the sputtering system 1, a stage 12 is provided at a position close to the bottom wall 11b. The stage 12 supports the wafer W. The stags 12 has a plate 12a, a shaft 12b, and a support portion 12c. The plate 12a is formed in a disk-like shape, for example, and has a surface 12d orthogonal to the V direction. The plate 12a supports the wafer W on the surface 12d in a manner such that a surface wa of the wafer W conforms to a surface orthogonal to the V direction. The shaft 12b protrudes in a direction opposite to the V direction from the support portion 12c, and is connected to the plate 12a. The plate 12a is supported by the support portion 12c via the shaft 12b. The support portion 12c can change a position of the shaft 12b in the V direction. For changing a position in the V direction, the support portion 12c may have a mechanism that can change a fixing position (holding position) of the shaft 12b, or may have an actuator including a motor, a rotation-linear motion converting mechanism, or the like that can electrically change the position in the V direction of the shaft 12b. When the position in the V direction of the shaft 12b is changed, a position in the V direction of the plate 12a also is changed. The positions of the shaft 12b and plate 12a can be set in multiple steps or in a stepless (continuously variable) manner. The stage 12 (plate 12a) is an example of a workpiece placement unit. The stage 12 can be referred to as a workpiece support unit, a position changing unit, and a position adjusting unit.

A collimator 13 is arranged between the top wall 11a and the stage 12. The collimator 13 is supported by the peripheral wall 11c of the chamber 11. The collimator 13 is formed in a substantially disk-like shape, and has a surface 13a and a surface 13b opposite to the surface 13a. The surfaces 13a and 13b are orthogonal to the V direction and extend in a planar shape along the H direction. A thickness direction of the collimator 13 is the V direction.

The collimator 13 is provided with a plurality of through holes 13c penetrating the surface 13a and the surface 13b. Additionally, the through hole 13c is opened toward the side of the target T, namely, the side of the top wall 11a, and also is opened toward the side of the wafer W, namely, the side of the stage 12.

The through hole 13c has a circular cross section, for example, and extends along the V direction. In other words, the through hole 13c is formed in a cylindrical shape (cylindrical surface shape). The cross-sectional shape of the through hole 13c is not limited to a circular shape, but may also be a polygonal shape such as a regular hexagon, for example. Additionally, the through holes 13c may be arranged substantially uniform at a same intervals within the surface 13a (or within the surface 13b), or an arrangement interval and a size (cross-sectional area or the like) of the through holes 13c may be different depending on a place of the surface 13a.

The particles P pass through the through hole 13c thus extending along the V direction, and thereby the particles P are rectified in the V direction. Therefore, the collimator 13 is referred to as a rectifying device or a rectifying member. A side surface 13d defining the through hole 13c can be referred to as a rectifying portion. Additionally, the side surface 13d can also be referred to as a peripheral surface or an inner surface. The surface 13a is an example of a first surface, and the surface 13b is an example of a second surface.

For example, a peripheral wall 11c of the chamber 11 is provided with a discharge port 11d. A pipe (not illustrated) extending from the discharge port 11d is connected to, for example, a suction pump (vacuum pump not illustrated). A gas contained inside the processing chamber R is discharged from the discharge port 11d by actuation of the suction pump, and the pressure inside the processing chamber R is decreased. The suction pump can suck the gas until a substantially vacuum state is obtained.

For example, the peripheral wall 11c of the chamber 11 is provided with an introduction port 11e. A pipe (not illustrated) extending from the introduction port 11e is connected to, for example, a tank (not illustrated). An inert gas such as an argon gas is contained in the tank, for example. The inert gas contained inside the tank can be introduced into the processing chamber R.

For example, the peripheral wall 11c of the chamber 11 is provided with a transparent window 11f. The collimator 13 can be photographed through the window 11f by a camera 20 arranged outside the chamber 11. A state of the collimator 13 can be confirmed from an image photographed by the camera 20 by image processing. Note that the transparent window 11f may be covered with a lid, a cover, a door, or the like which is detachable or openable/closable. Additionally, the peripheral wall 11c may be provided with an opening portion (through hole) instead of the transparent window 11f, and additionally the opening portion may be provided with an openable/closable lid. For example, the lid, cover, door, or the like can cover the window 11f or an opening portion while the sputtering system 1 is actuated, and can open the window 11f or the opening portion in a state where the sputtering system 1 is not actuated.

In the sputtering system 1 having the above-described structure, when voltage is applied to the target T, the argon gas that has been introduced into the processing chamber R is ionized and plasma is generated. The argon ions collide with the target T, thereby ejecting the particles P of the metal material (film forming material) constituting the target T from a lower surface ta of the target T, for example. Thus, the target T emits the particles P.

Meanwhile, the directions in which the particles P fly from the lower surface ta of the target T are distributed in accordance with the cosine law (Lambert's cosine law). In other words, the particles P flying from a certain point of the lower surface ta of the target T fly the most in a normal direction (vertical direction, V direction) of the lower surface ta. Therefore, the normal direction is an example of the direction in which the target T placed on the top wall 11a or the backing plate (source placement member) emits at least one particle. The number of particles which fly in a direction inclined at an angle θ (obliquely intersecting) with respect to the normal direction is approximately proportional to a cosine (cos θ) of the number of particles flying in the normal direction.

The particles P are minute particles of the metal material of the target T. The particle P may also be a particle of a substance such as a molecule, an atom, an atomic nucleus, an elementary particle, and vapor (a vaporized substance). Furthermore, the particles P may contain a positive ion P1 such as a copper ion positively charged.

In the present embodiment, the collimator 13 is magnetized in order to deflect, in the V direction, the positive ion P1 thus positively charged. As an example, the collimator 13 is magnetized such that the side of the wafer W, namely, the side of the surface 13b becomes an N pole, and the side of the target T, namely, the side of the surface 13a becomes an S pole. The collimator 13 is an example of a magnetized magnetic body and also is an example of a magnetic field generation unit. The collimator 13 may be entirely magnetized or a part of the collimator 13, for example, a peripheral portion of the through hole 13c may be partly magnetized.

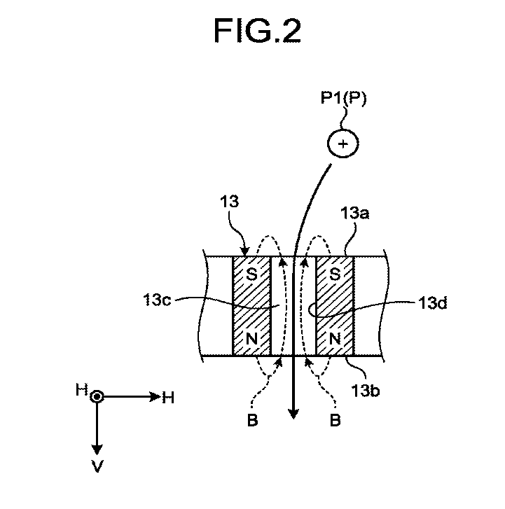

FIG. 2 is a partial cross-sectional view including the through hole 13c of the collimator 13. As illustrated in FIG. 2, a magnetic field B directed from the surface 13b to the surface 13a is formed inside the through hole 13c by the magnetized collimator 13.

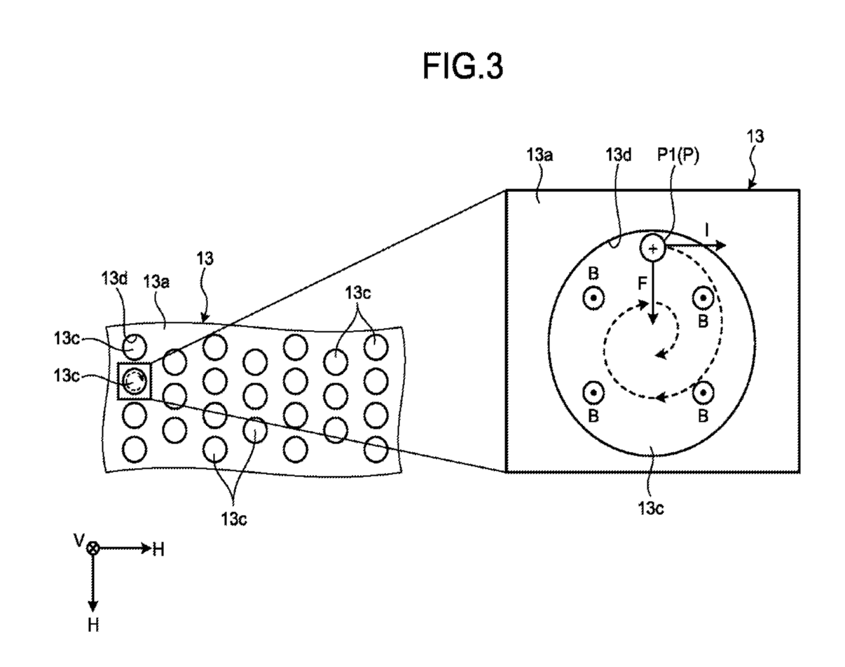

FIG. 3 is an explanatory view including a plan view of the collimator 13 and an enlarged view of a part thereof. As illustrated in the enlarged view of FIG. 3, the positive ion P1 receives Lorentz force F by the magnetic field B formed inside the through hole 13c, and is moved in the V direction inside the through hole 13c while swirling. During this time, a swirling radius of the positive ion P1 is gradually decreased as the positive ion is moved in the V direction. All of the positive ions P1 having entered the through hole 13c are subjected to such force by the magnetic field B, and therefore, after coming out of the through hole 13c, the positive ions are directed to one point (focal point not illustrated) located substantially immediately below the through hole 13c and spaced from the surface 13b in the V direction. A deviated amount of the positive ion P1 in the H direction is a value corresponding to an H direction component of a velocity vector when the positive ion P1 enters the through hole 13c, but the positive ion P1 having entered the through hole 13c is deflected and converges at the focal point by the magnetic field B formed inside the through hole 13c. In the collimator 13, the magnetic field B formed in the through hole 13c and in a periphery thereof functions as a magnetic lens of the positive ion P1. According to the present embodiment, unevenness of a film thickness of the wafer W depending on a location thereof can be adjusted so as to be reduced not only by an original rectifying effect on the particles P by the collimator 13 but also by a magnetic converging effect by the magnetic lens.

Therefore, the positive ions P1 can be appropriately converged on the wafer W by appropriately adjusting or setting a distance between the collimator 13 and the stage 12, for example, a distance L between the surface 13b of collimator 13 and the surface 12d of the stage 12 as illustrated in FIG. 1. For example, the distance L can be adjusted or set by changing the position of the shaft 12b with respect to the support portion 12c of the stage 12.

Here, the focal point may be set to a predetermined position of the wafer W such as the surface wa of the wafer W, or may be set to a position slightly displaced (offset) from the wafer W in one direction or the other direction of the V direction, namely, an upward or downward direction in FIG. 1. In the case where the focal point is offset, for example, a reaching range of the positive ion P1 corresponding to each of the through holes 13c can be more enlarged on the surface wa of the wafer W, compared to a case where the focal point of the magnetic lens of the through hole 13c is set on the surface wa of the wafer W. Therefore, there may be a case where unevenness of the film thickness of the wafer W depending on the location thereof can be further reduced.

Furthermore, for example, in a case where film formation processing is performed over a relatively long period, deposits of the particles P may be left on the surface 13a and the side surface 13d of the collimator 13. Consequently, a region inside the through hole 13c where the positive ions P1 can pass is narrowed, and therefore, there is a risk in which the focal point of the positive ions P1 is changed with time. Additionally, in a case where the surface 13a and the side surface 13d are eroded by influence of the plasma or the like, temporal change of the focal point of the positive ions P1 can be caused. In this point, according to the present embodiment, the state of the collimator 13 can be confirmed by a photographed image by the camera 20 or visual check via the window 11f or the opening portion. Therefore, the distance L can be variable in accordance with the state of the collimator 13, and unevenness of the film thickness of the wafer W depending on the location thereof can be further reduced.

As described above, in the present embodiment, the collimator 13 is magnetized so as to generate the magnetic field B directed from the side of the surface 13b (second surface) to the side of the surface 13a (first surface) inside the through hole 13c of the collimator 13. Therefore, since the swirling radius is decreased when the positive ions P1 pass through the through hole 13c while spirally swirling inside the through hole 13c, the positive ion P1 converges at a position away from the through hole 13c in the V direction. Therefore, for example, unevenness of the film thickness of the wafer W depending on the location thereof tends to be reduced not only by the original rectifying effect on the particles P provided by the collimator 13 but also by the magnetic converging effect on positively charged particles such as the positive ions P1.

Note that the magnetic field B may also be a magnetic field directed from the side of the surface 13a (first surface) to the side of the surface 13b (second surface). In this case, functions and effects similar to the above-described functions and effects can be obtained for negative ions.

Furthermore, in the present embodiment, the collimator 13 is the magnetic body, namely, the magnetic field generation unit. Therefore, for example, a structure in which a magnetic convergence effect on the positive ions P1 can be obtained can be formed in a relatively simple manner.

Moreover, the distance between the collimator 13 and the plate 12a (workpiece placement unit) of the stage 12, for example, the distance L between the surface 13b of the collimator 13 and the surface 12d of the plate 12a can be variable. Therefore, for example, unevenness of the film thickness of the wafer W depending on a location thereof can be suppressed.

### Second Embodiment

A collimator 13A of the present embodiment has a structure similar to that of a collimator 13 of a first embodiment described above. Therefore, according to the present embodiment also, similar functions and results (effects) based on the similar structure can be obtained. However, the present embodiment differs from the above-described first embodiment in that the collimator 13A includes an electromagnet. For example, the collimator 13A can be installed inside a chamber 11 of the first embodiment, in place of the collimator 13.

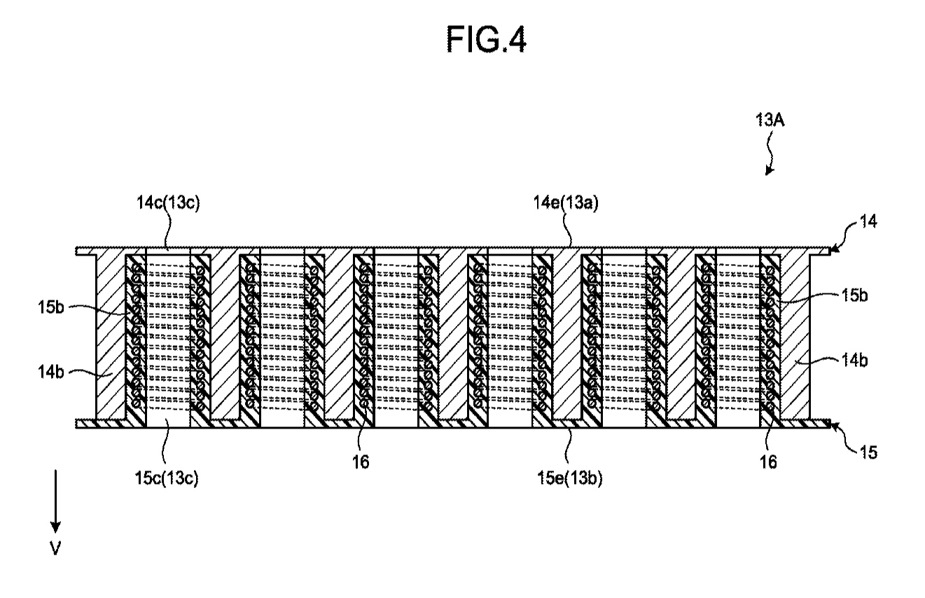

FIG. 4 is a cross-sectional view of the collimator 13A of the present embodiment. As illustrated in FIG. 4, the collimator 13A has a plurality of coils 16 wound around the respective through holes 13c. The coil 16 is formed of a winding wire obtained by winding, for example, a copper wire or the like. Additionally, the coil 16 may have a coil bobbin.

The coil 16 can function as an electromagnet by making current flow through non-illustrated wiring or the like provided inside the collimator 13A. Therefore, in the present embodiment also, a magnetic field directed from the side of a surface 13b to the side of a surface 13a can be formed in the through hole 13c. Additionally, according to the present embodiment, strength of the magnetic field can be changed by changing a value of the current flowing in the coil 16. When the strength of the magnetic field is changed, a distance to a focal point is changed. Therefore, according to the present embodiment, the strength of the magnetic field generated in the through hole 13c is changed by, for example, changing the magnitude (current value) of the current flowing in the coil 16, and consequently, unevenness of a film thickness of a wafer W depending on a location thereon can be reduced. Additionally, the direction of the magnetic field generated in the coil 16 is changed by changing the direction of the current flowing through the coil 16, and consequently, an ion to be a target of the above-described functions and effects by the magnetic field can be switched between a positive ion and a negative ion. The coil 16 is an example of a magnetic field generation unit.

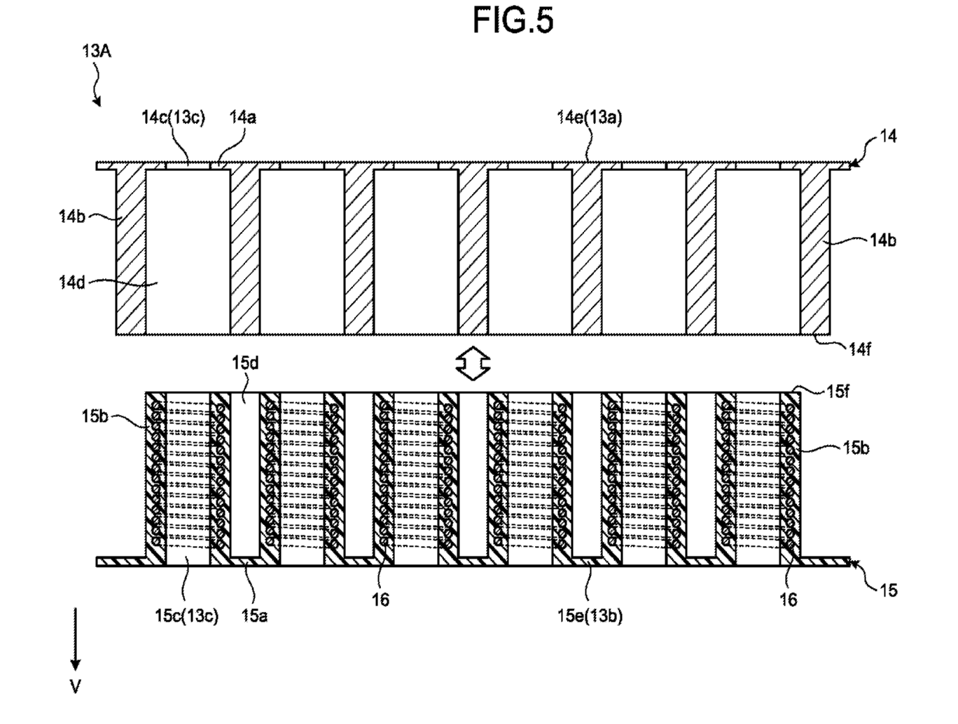

FIG. 5 is an exploded cross-sectional view of the collimator 13A. As illustrated in FIGS. 4 and 5, in the present embodiment, the collimator 13A is formed by integrating a first component 14 (first member) and a second component 15 (second member). For example, the first component 14 positioned on the side of a target T is formed of ceramics having relatively high resistance to plasma. On the other hand, the second component 15 including (supporting) the coil 16 and the wiring (not illustrated) is formed of a synthetic resin material having high formability (plastic, engineering plastic). In this case, the coil 16 and the wiring can be relatively easily incorporated in the second component 15 by insert molding or the like. Note that the coil 16 may be incorporated in the second component 15 by a method other than insert molding, for example, by being housed in a recessed portion provided in the second component 15, being attached to a rod-like portion provided in the second component 15, being bonded to the second component 15, or the like.

Furthermore, the collimator 13A may be formed in a manner such that the first component 14 and the second component 15 can be disassembled. In this case, connection between the first component 14 and the second component 15 can take various kinds of forms, for example, press fitting, snap fitting, coupling via a coupling tool or a component (not illustrated), or the like. With the above-described structure, for example, in the case where the second component 15 is eroded by plasma or the through hole 13c is narrowed due to deposits, the second component 15 is separated from the collimator 13A (from the first component 14) and can be replaced with a new second component 15. In other words, the second component 15 of the collimator 13A is a replaceable component (expendable item). With this structure, for example, waste of a material and a maintenance cost are easily reduced compared to a case where the entire collimator 13A is a replaceable component (expendable item). Additionally, since not only strength of the magnetic field but also a distance (focal length) to a position of convergence performed by the through hole 13c can be changed by, for example, preparing a plurality of second components 15 each including a coil 16 having a different specification and by changing a second component 15 to be incorporated in the collimator 13A, unevenness of the film thickness of the wafer W depending on the location thereon can be reduced. Furthermore, specifications such as a length, a size, and the like of the through hole 13c can also be changed.

The first component 14 may also be a replaceable component. In this case, for example, a plurality of first components 14 each having a different dimension, a material, and the like is prepared, and a first component 14 to be incorporated in the collimator 13A can be changed. With this structure, for example, specifications such as the length, size, and the like of the through hole 13c can be changed.

As illustrated in FIG. 5, the first component 14 of the collimator 13A has a disk-like top wall portion 14a and a columnar body 14b extending in a V direction from the top wall portion 14a. A surface 14f of the body 14b is provided with a cylindrical recessed portion 14d opened in the V direction. The top wall portion 14a is provided with a through hole 14c penetrating between a surface 14e and the recessed portion 14d. The through hole 14c is a part of the through hole 13c. In other words, the body 14b is also a protruding portion that protrudes in the V direction from the top wall portion 14a. The surface 14e of the top wall portion 14a is the surface 13a of the collimator 13A.

Additionally, the second component 15 of the collimator 13A has a disk-like bottom wall portion 15a and a plurality of protruding portions 15b extending from the bottom wall portion 15a in a direction opposite to the V direction. In a state where the first component 14 and the second component 15 are integrated, the protruding portions 15b are housed in the recessed portion 14d provided in the first component 14. The protruding portion 15b is provided with a through hole 15c which has a diameter same as that of the through hole 14c provided at the top wall portion 14a, and is connected thereto in a state that the first component 14 and the second component 15 are integrated. The through hole 15c is a part of the through hole 13c of the second component 15 of the collimator 13A. Additionally, in a state where the first component 14 and the second component 15 are integrated, the body 14b of the first component 14 is housed in each of gaps 15d provided between the plurality of protruding portions 15b. A surface 15e of the bottom wall portion 15a is the surface 13b of the collimator 13A.

As it can be grasped from comparison with the V direction in FIG. 4, the top wall portion 14a and the body 14b of the first component 14 cover the plurality of protruding portions 15b of the second component 15 from the side of the target T. In other words, the first component 14 suppresses the second component 15 from being eroded by plasma. The first component 14 may also be referred to as a cover or a protective member.

As described above, in the present embodiment, the collimator 13A includes the coil 16 wound around the through hole 13c. Therefore, for example, since not only the strength of the magnetic field but also the distance to the position of convergence performed by the through hole 13c can be changed by the magnitude of the current (current value) flowing in the coil 16, unevenness of the film thickness of the wafer W depending on the location thereon can be reduced. Additionally, for example, the direction of the magnetic field is changed by changing the direction of the current flowing in the coil 16, and an ion to be a target of the above-described functions and effects by the magnetic field can be switched between a positive ion and a negative ion.

Furthermore, the collimator 13A is formed by integrating the first component 14 and the second component 15. Therefore, since the functions can be divided between the first component 14 and the second component 15, two trade-off features are easily compatible. For example, in the case where the first component 14 is a component such as ceramics having plasma resistance higher than that of the second component 15, and the second component 15 is a component such as a synthetic resin material that can easily incorporate the coil 16, both of plasma resistance and manufacturability are easily compatible at a higher level. Meanwhile, a magnetic body such as a permanent magnet may be supported in the second component 15, in place of the coil 16.

Additionally, the collimator 13A has the structure in which that the second component 15 or the first component 14 is formed in a replaceable (detachable) manner. Therefore, for example, waste of materials and costs for manufacturing and maintenance are easily reduced compared to the case where the entire collimator 13A is to be replaced.

Furthermore, the first component 14 has higher plasma resistance than the second component 15 does, and covers the second component 15 from the opposite side of the stage 12 (workpiece placement unit), namely, from the side of the target T or the side of the top wall 11a. Therefore, for example, the first component 14 prevents the second component 15 from being eroded by plasma.

Modification

A collimator 13B of the present modification has a structure similar to a collimator 13 of a first embodiment described above. Therefore, in the present modification also, similar functions and results (effects) based on the similar structure can be obtained. For example, the collimator 13B can be installed inside a chamber 11 of the first embodiment, in place of the collimator 13.

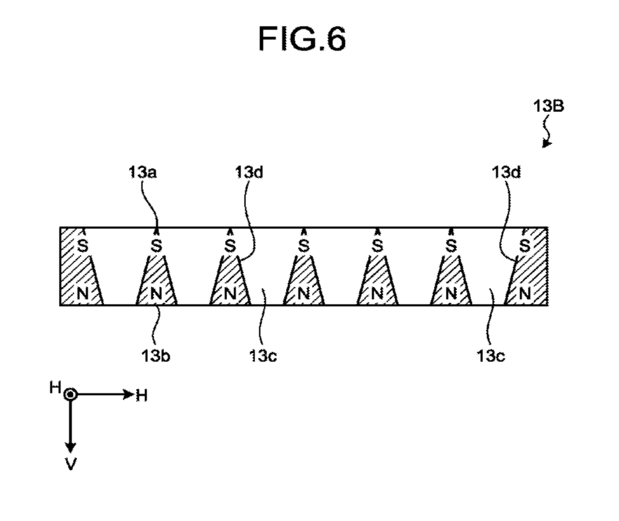

FIG. 6 is a cross-sectional view of the collimator 13B according to the present modification. As illustrated in FIG. 6, in the collimator 13B of the present modification, a cross-sectional area of a cross section orthogonal to a V direction of a through hole 13c is gradually decreased from a surface 13a to a surface 13b. With this structure, the area of the surface 13a is reduced, and therefore, an amount of deposits of particles P on the surface 13a tends to be decreased.

Such inclination of the through hole 13c is also applicable to a split type collimator 13A like a second embodiment described above or to other collimators.

While the embodiments of the present invention have been exemplified above, the above-described embodiments are merely examples and are not intended to limit the scope of the invention. The embodiments can be implemented in various other forms, and various kinds of omissions, substitutions, combinations, and changes can be made without departing from the gist of the invention. The embodiments are included in the scope and gist of the invention and also included in the invention described in the claims and equivalent thereto. Additionally, the structures and shapes of the embodiments can be partly replaced for implementation. Furthermore, the specifications (structure, type, direction, shape, size, length, width, thickness, height, angle, number, arrangement, position, material, and the like) of each structure, shape, and the like can be appropriately changed for implementation. For example, the processing apparatus may also be a device other than a sputtering system such as a CVD system.

1. A processing apparatus comprising:
a container;
a workpiece placement unit on which a workpiece is to be placed so that particles are stacked on the workpiece, the workpiece placement unit being provided inside the container;
a collimator having a first surface, a second surface opposite to the first surface, and a through hole penetrating the first surface and the second surface, the collimator being provided inside the container; and
a magnetic field generation unit configured to generate a magnetic field between the first surface and the second surface inside the through hole, the magnetic field generation unit being provided inside the container.

2. The processing apparatus according to claim 1, wherein the second surface faces the workpiece when the workpiece is placed on the workpiece placement unit.

3. The processing apparatus according to claim 1, wherein the magnetic field is either a magnetic field directed from the second surface side to the first surface side inside the through hole or a magnetic field directed from the first surface side to the second surface side inside the through hole.

4. The processing apparatus according to claim 1, wherein the magnetic field generation unit includes a magnetic body having a magnetization direction extending along a penetrating direction of the through hole.

5. The processing apparatus according to claim 1, wherein the magnetic field generation unit includes a coil wound in a manner surrounding the through hole.

6. The processing apparatus according to claim 1, wherein the collimator includes a first component and a second component integrated with the first component and supporting the magnetic field generation unit.

7. The processing apparatus according to claim 6, wherein the collimator has the second component formed in a replaceable manner.

8. The processing apparatus according to claim 6, wherein the second component includes a synthetic resin material.

9. The processing apparatus according to claim 6, wherein the first component has plasma resistance higher than the second component does, and covers the second component from an opposite side of the workpiece placement unit.

10. The processing apparatus according to claim 6, wherein the first component includes ceramics.

11. The processing apparatus according to claim 1, wherein the collimator and the workpiece placement unit are configured to have a variable distance therebetween.

12. The processing apparatus according to claim 2, wherein a cross-sectional area of the through hole in a cross section orthogonal to the penetrating direction is gradually decreased from the first surface to the second surface.

13. A collimator comprising:
a first surface;
a second surface opposite to the first surface; and
a magnetic field generation unit configured to generate a magnetic field between the first surface and the second surface inside a through hole penetrating between the first surface and the second surface.
